(19) United States
(12) Patent Application Publication
(10) Pub. No.: US 2017/0294345 A1
(43) Pub. Date: Oct. 12, 2017

(54) METHOD AND APPARATUS FOR MANUFACTURING SEMICONDUCTOR DEVICE

(71) Applicant: BOE Technology Group Co., Ltd., Beijing (CN)

(72) Inventors: Xiaoyong Lu, Beijing (CN); Hongwei Tian, Beijing (CN); Yueping Zuo, Beijing (CN); Xiaowei Xu, Beijing (CN); Wenqing Xu, Beijing (CN); Chunping Long, Beijing (CN)

(21) Appl. No.: 15/512,372

(22) PCT Filed: Mar. 3, 2016
(86) PCT No.: PCT/CN2016/075422

§ 371 Date: Mar. 17, 2017

(30) Foreign Application Priority Data
Mar. 23, 2015 (CN) 201510127926.1

(51) Int. Cl. H01L 21/768

(52) U.S. Cl. CPC H01L 21/76877; H01L 21/76814

(57) ABSTRACT

Provided are a method and an apparatus for manufacturing a semiconductor device. The method comprises: forming a first wiring layer on a base substrate; forming an interlayer dielectric layer on the first wiring layer, with contact holes being provided in the interlayer dielectric layer; subjecting bottoms of the contact holes to a dry cleaning process; and forming a second wiring layer on the interlayer dielectric layer, wherein the second wiring layer is electrically connected to the first wiring layer via the contact holes.

### CROSS-REFERENCE TO RELATED APPLICATION

This application is a Section 371 National Stage Application of International Application No. PCT/CN2016/075422, filed on Mar. 3, 2016, which published as WO 2016/150287 A1, on Sep. 29, 2016, and claims priority to Chinese Patent Application No. 201510127926.1, filed on Mar. 23, 2015, which are incorporated by reference herein in their entirety.

### TECHNICAL FIELD

This present disclosure relates to the technical field of semiconductor processing, and particularly to a method for manufacturing a semiconductor device and an apparatus for manufacturing a semiconductor device.

### BACKGROUND

Among current methods for manufacturing semiconductor devices, contaminants are left over after the patterning process, and the residual contaminants are removed and etched by using wet cleaning processes with hydrofluoric acid, etc. However, methods described above will bring about hydrofluoric acid residues and also fail to prevent the generation of native oxide layers. The contact resistance is increased and the performance of the semiconductor device is reduced by residual contaminants and native oxide layers at the bottom of the contact holes.

### SUMMARY

According to an embodiment of this disclosure, there is provided a method for manufacturing a semiconductor device, comprising: forming a first wiring layer on a base substrate; forming an interlayer dielectric layer on the first wiring layer, with contact holes being provided in the interlayer dielectric layer; subjecting bottoms of the contact holes to a dry cleaning process; and forming a second wiring layer on the interlayer dielectric layer, wherein the second wiring layer is electrically connected to the first wiring layer via the contact holes.

In some embodiments, the first wiring layer may comprise a conductive material or a semiconductor material, and in some embodiments, the second wiring layer may comprise a conductive material.

In some embodiments, the dry cleaning process may comprise a plasma cleaning process.

In some embodiments, the plasma cleaning process may comprise an argon plasma cleaning process.

In some embodiments, before subjecting the bottoms of the contact holes to a dry cleaning process, the method may further comprise: subjecting the contact holes to a first wet cleaning process; and subjecting the contact holes to a second wet cleaning process.

In some embodiments, the first wet cleaning process for the contact holes may be performed by using an oxidative acidic solution, and a second wet cleaning process for the contact holes may be performed by using an oxidative alkaline solution.

In some embodiments, the second wiring layer may be formed by a sputtering process or vapor deposition process.

In some embodiments, the conductive material may comprise a metal material, and in some embodiments, the semiconductor material may comprise amorphous silicon or polycrystalline silicon.

According to an embodiment of this disclosure, further provided is an apparatus for manufacturing a semiconductor device, wherein the semiconductor device comprises a base substrate, a first wiring layer provided on the base substrate, an interlayer dielectric layer provided on the first wiring layer, with contact holes being provided in the interlayer dielectric layer, the apparatus comprising a pre-cleaning chamber, a reaction chamber, and a conveying chamber, wherein the pre-cleaning chamber and the reaction chamber are connected to the conveying chamber respectively; the pre-cleaning chamber is used for subjecting bottoms of the contact holes to a dry cleaning process; and the reaction chamber is used for forming a second wiring layer on the interlayer dielectric layer, wherein the second wiring layer is electrically connected to the first wiring layer via the contact holes.

In some embodiments, the reaction chamber may comprise a sputtering or vapor deposition chamber.

In some embodiments, the base substrate subjected to a dry cleaning process may be moved from the pre-cleaning chamber to the reaction chamber through the conveying chamber.

In some embodiments, the apparatus may further comprise a heating chamber connected to the conveying chamber, which is used for heating the base substrate having the contact holes formed thereon, before subjecting the bottoms of the contact holes to a dry cleaning process.

In some embodiments, the apparatus may further comprise a loading and locking chamber connected to the conveying chamber, which is used for delivering a semiconductor device to be processed to the conveying chamber and is used for withdrawing the semiconductor device processed from the apparatus.

### BRIEF DESCRIPTION OF THE DRAWINGS

FIG. 1 is a flow chart of a method for manufacturing a semiconductor device according to an embodiment of this disclosure.

FIG. 2 is a flow chart of a method for manufacturing a semiconductor device according to an embodiment of this disclosure.

FIG. 3 is a structural schematic view of an apparatus for manufacturing a semiconductor device according to an embodiment of this disclosure.

### DESCRIPTION OF EMBODIMENTS

In order to allow the person skilled in the art to better understand the technical solution of this disclosure, the method for manufacturing a semiconductor device and the apparatus for manufacturing a semiconductor device will be described in details in conjunction with accompanying drawings.

FIG. 1 is a flow chart of a method for manufacturing a semiconductor device according to an embodiment of this disclosure. As shown in FIG. 1, the method comprises the following Step 1001 to Step 1004.

Step 1001 comprises forming a first wiring layer on a base substrate.

In this step, the constituent material of the first wiring layer may comprise a conductive material or a semiconductor material. For example, the conductive material comprises a metal material, and the semiconductor material comprises amorphous silicon or polycrystalline silicon. In addition to the achievement of the function of the semiconductor device, the use of the materials described above may also improve the conduction performance of the first wiring layer and reduce the contact resistance. In particular, a first wiring layer thin film is formed on the base substrate, and the constituent material of the first wiring layer thin film includes a metal material, amorphous silicon, or polycrystalline silicon. Thereafter, the first wiring layer thin film is treated by an etching process to form the first wiring layer.

Step 1002 comprises forming an interlayer dielectric layer on the first wiring layer, with contact holes being provided in the interlayer dielectric layer.

In this step, an interlayer dielectric (ILD) layer is formed on the first wiring layer, wherein the constituent material of the interlayer dielectric layer is at least one of silicon oxide and silicon nitride. Next, a photoresist is applied on the interlayer dielectric layer, and the photoresist is exposed and developed using a mask plate, to form a photoresist remaining area and a photoresist removing area. The photoresist removing area corresponds to a pattern area for forming contact holes, and the photoresist remaining area corresponds to an area other than the pattern area. Finally, the interlayer dielectric layer is etched so as to form contact holes.

Step 1003 comprises subjecting the bottoms of the contact holes to a dry cleaning process.

In this step, the dry cleaning process comprises a plasma cleaning process. For example, the plasma cleaning process comprises an argon plasma cleaning process. The plasma cleaning process can remove residual contaminants and native oxide layers, and will not bring about new contaminants. In this step, process parameters for the argon plasma cleaning are set as follows: a chamber pressure in a range of 3 mTorr to 80 mTorr, a process gas flow rate in a range of 5 sccm to 500 sccm, a process time in a range of 5 s to 60 s, and a radio frequency power in a range of 50 W to 400 W. In some embodiments, process parameters of the argon plasma cleaning may be set as follows: a chamber pressure of 10 mTorr, a process gas flow rate of 100 sccm, a process time of 15 s, and a radio frequency power of 100 W. By using the argon plasma cleaning process to treat the bottom and side surfaces of the contact holes, oxide layers formed due to autoxidation in the contact holes are removed, and new contaminants will not be brought about.

Moreover, in some embodiments, before said Step 1003, the contact holes may be subjected to a first wet cleaning process by using an oxidative acidic solution, and to a second wet cleaning process by using an oxidative alkaline solution. For example, a wet cleaning process is performed by using a hydrofluoric acid (HF) solution at a hydrogen fluoride concentration of 0.25% to 2%, and the treatment time is in a range of 10 s to 100 s. By means of the first wet cleaning process and the second wet cleaning process, residual contaminants generated in a previous etching process (e.g., a process of forming contact holes by etching) may be removed, so as to achieve preliminary cleaning of the contact holes.

Step 1004 comprises forming a second wiring layer on the interlayer dielectric layer, wherein the second wiring layer is electrically connected to the first wiring layer via the contact holes.

In this step, the constituent material of the second wiring layer includes a conductive material. That is, the second wiring layer is a conductive layer. For example, the second wiring layer is formed by a process such as sputtering, evaporation, etc. In practical application, it is required to form contact holes in the interlayer dielectric layer, for connecting to a source electrode region and a drain electrode region respectively. Therefore, the process of forming the second wiring layer is also referred to as SD sputtering. By forming the second wiring layer through a sputtering process, the uniformity of the second wiring layer may be improved, and due to a high sputtering rate in the sputtering process, the efficiency of the process may be improved.

In some embodiments, the cleaning processes described above are continuously performed without time delay, so as to maintain the cleanness of exposed parts of the contact holes. After the dry cleaning process is performed, a second wiring layer is also formed on the interlayer dielectric layer without time delay. Since there is no time delay, it is possible to prevent regeneration of residual contaminants and native oxide layers, as a result, the contact resistance is reduced and the performance of the semiconductor device is improved.

In the method for manufacturing a semiconductor device according to embodiments of this disclosure, a first wiring layer is formed on a base substrate; an interlayer dielectric layer is formed on the first wiring layer, with contact holes being provided in the interlayer dielectric layer; the bottoms of the contact holes are subjected to a dry cleaning process, and a second wiring layer is formed on the interlayer dielectric layer, wherein the second wiring layer is electrically connected to the first wiring layer via the contact holes. The method for manufacturing a semiconductor device of embodiments of this disclosure can remove residual contaminants and native oxide layers on the bottoms of the contact holes, and can also prevent regeneration of residual contaminants and native oxide layers, such that the contact resistance is reduced and the performance of the semiconductor device is improved.

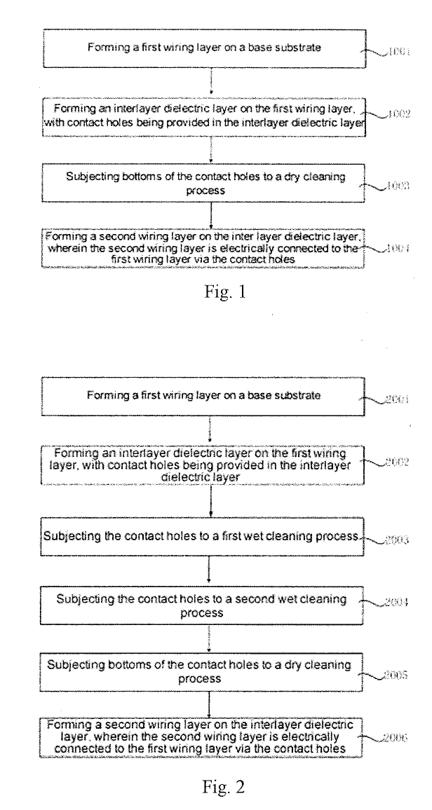

FIG. 2 is a flow chart of a method for manufacturing a semiconductor device according to embodiments of this disclosure. As shown in FIG. 2, the method comprises the following Step 2001 to Step 2006.

Step 2001 comprises forming a first wiring layer on a base substrate.

Step 2002 comprises forming an interlayer dielectric layer on the first wiring layer, with contact holes being provided in the interlayer dielectric layer.

Step 2003 comprises subjecting the contact holes to a first wet cleaning process.

Step 2004 comprises subjecting the contact holes to a second wet cleaning process.

In some embodiments, the first wet cleaning process for the contact holes is performed by using an oxidative acidic solution, and the second wet cleaning process for the contact holes is performed by using an oxidative alkaline solution. For example, a wet cleaning process is performed by using a hydrofluoric acid (HF) solution at a hydrogen fluoride concentration in a range of 0.25% to 2%, and the treatment time is in a range of 10 s to 100 s. By means of the first wet cleaning process and the second wet cleaning process, residual contaminants generated in a previous etching process (e.g., a process of forming contact holes by etching) may be removed, so as to achieve preliminary cleaning of the contact holes.

Step 2005 comprises subjecting bottoms of the contact holes to a dry cleaning process.

In this step, the dry cleaning process comprises a plasma cleaning process. For example, the plasma cleaning process comprises an argon plasma cleaning process. On premise of removing residual contaminants and native oxide layers, the plasma cleaning process will not bring about new contaminants. In this step, process parameters for the argon plasma cleaning may be set as follows: a chamber pressure in a range of 3 mTorr to 80 mTorr, a process gas flow rate in a range of 5 sccm to 500 sccm, a process time in a range of 5 s to 60 s, and a radio frequency power in a range of 50 W to 400 W. In some embodiments, process parameters of the argon plasma cleaning are set as follows: a chamber pressure of 10 mTorr, a process gas flow rate of 100 sccm, a process time of 15 s, and a radio frequency power of 100 W. Since the bottom and side surfaces of the contact holes are treated by using the argon plasma cleaning process, oxide layers formed due to autoxidation in the contact holes are removed, and new contaminants will not be brought about.

Step 2006 comprises forming a second wiring layer on the interlayer dielectric layer, wherein the second wiring layer is electrically connected to the first wiring layer via the contact holes.

In the method for manufacturing a semiconductor device according to embodiments of this disclosure, a first wiring layer is formed on a base substrate; an interlayer dielectric layer is formed on the first wiring layer, with contact holes being provided in the interlayer dielectric layer; the contact holes are subjected to a wet cleaning process, and then the bottoms of the contact holes are subjected to a dry cleaning process; and a second wiring layer is formed on the interlayer dielectric layer, wherein the second wiring layer is electrically connected to the first wiring layer via the contact holes. The method for manufacturing a semiconductor device according to embodiments of this disclosure can remove residual contaminants and native oxide layers on the bottoms of the contact holes, and can also prevent regeneration of residual contaminants and native oxide layers in the wet cleaning process, such that the contact resistance is reduced and the performance of the semiconductor device is improved.

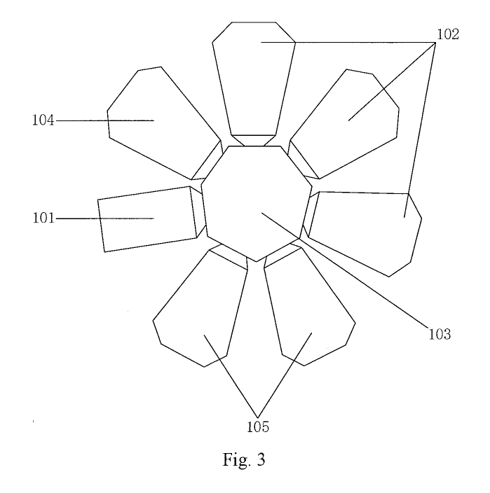

FIG. 3 is a structural schematic view of an apparatus for manufacturing a semiconductor device according to embodiments of this disclosure. As shown in FIG. 3, the apparatus for manufacturing a semiconductor device comprises a pre-cleaning chamber 101, a reaction chamber 102, and a conveying chamber 103, wherein the pre-cleaning chamber 101 and the reaction chamber 102 are connected to the conveying chamber 103 respectively. The number of the reaction chambers 102 may be plural. In some embodiments, the number of the reaction chambers 102 is three. Moreover, the apparatus may further comprise a heating chamber 104 and a loading and locking chamber 105 which are connected to the conveying chamber 103. The number of the loading and locking chambers 105 may be plural. In some embodiments, the number of the loading and locking chambers 105 is two.

In some embodiments, the steps of forming the semiconductor device comprise forming a first wiring layer on a base substrate, and the constituent material of the first wiring layer may comprise a conductive material or a semiconductor material. For example, the conductive material comprises a metal material, and the semiconductor material comprises amorphous silicon or polycrystalline silicon. In particular, a first wiring layer thin film is formed on the base substrate, wherein the constituent material of the first wiring layer thin film includes a metal material, amorphous silicon, or polycrystalline silicon. Thereafter, the first wiring layer thin film is treated by an etching process to form the first wiring layer. Moreover, an interlayer dielectric (ILD) layer is formed on the first wiring layer, wherein the constituent material of the interlayer dielectric layer is at least one of silicon oxide and silicon nitride. Moreover, a photoresist is applied on the interlayer dielectric layer, and the photoresist is exposed and developed using a mask plate to form a photoresist remaining area and a photoresist removing area. The photoresist removing area corresponds to a pattern area where contact holes are formed, and the photoresist remaining area corresponds to an area other than the pattern area. Finally, the interlayer dielectric layer is etched to form contact holes.

When the apparatus is in operation, the base substrate on which the contact holes are formed is passed from the loading and locking chamber 105 to the conveying chamber 103, and then passed from the conveying chamber 103 to the heating chamber 104. After being heated in the heating chamber 104, the base substrate is passed to the conveying chamber 103 again, and then passed from the conveying chamber 103 to the pre-cleaning chamber 101. In the pre-cleaning chamber 101, the bottoms of the contact holes are subjected to a dry cleaning process. For example, the dry cleaning process comprises a plasma cleaning process. For example, the plasma cleaning process comprises an argon plasma cleaning process. In embodiments of this disclosure, process parameters for the argon plasma cleaning may be set as follows: a chamber pressure in a range of 3 mTorr to 80 mTorr, a process gas flow rate in a range of 5 sccm to 500 sccm, a process time in a range of 5 s to 60 s, and a radio frequency power in a range of 50 W to 400 W. For example, process parameters of the argon plasma cleaning are set as follows: a chamber pressure of 10 mTorr, a process gas flow rate of 100 sccm, a process time of 15 s, and a radio frequency power of 100 W. In the pre-cleaning chamber 101, the contact holes are treated by using an argon plasma cleaning process to remove oxide layers formed due to autoxidation in the contact holes.

After the dry cleaning process, the unfinished semiconductor device is passed from the pre-cleaning chamber 101 to the conveying chamber 103, and then passed from the conveying chamber 103 to the reaction chamber 102. In the reaction chamber 102, a second wiring layer is formed on the interlayer dielectric layer, wherein the second wiring layer is electrically connected to the first wiring layer via the contact holes. The constituent material of the second wiring layer includes a conductive material. That is, the second wiring layer is a conductive layer. For example, the second wiring layer is formed by a process such as sputtering, vapor deposition, etc. After a dry cleaning process is performed, the second wiring layer is formed on the interlayer dielectric layer without time delay in the reaction chamber 102. Since there is no time delay, it is possible to prevent regeneration of residual contaminants and native oxide layers, such that the contact resistance is reduced and the performance of the semiconductor device is improved. After the sputtering process is finished, the semiconductor device is passed from the reaction chamber 102 to the conveying chamber 103, and then passed from the loading and locking chamber 105 to the outside of apparatus.

The apparatus for manufacturing a semiconductor device of according to embodiments of this disclosure can remove residual contaminants and native oxide layers on the bottoms of the contact holes, and can also prevent regeneration of residual contaminants and native oxide layers, such that the contact resistance is reduced and the performance of the semiconductor device is improved.

It should be understood that the above embodiments are merely exemplary embodiments used for illustrating the principle of this invention. However, this invention is not limited thereto. For those of ordinary skill in the art, various variations and modifications can be made without departing from the spirit and the substance of this invention. These variations and modifications are also considered in the scope protected by this invention.

1. A method for manufacturing a semiconductor device, comprising:
forming a first wiring layer on a base substrate;
forming an interlayer dielectric layer on the first wiring layer, with contact holes being provided in the interlayer dielectric layer;
subjecting bottoms of the contact holes to a dry cleaning process; and
forming a second wiring layer on the interlayer dielectric layer, wherein the second wiring layer is electrically connected to the first wiring layer via the contact holes.

2. The method according to claim 1, wherein the first wiring layer comprises a conductive material or a semiconductor material.

3. The method according to claim 1, wherein the dry cleaning process comprises a plasma cleaning process.

4. The method according to claim 3, wherein the plasma cleaning process comprises an argon plasma cleaning process.

5. The method according to claim 1, further comprising a step of subjecting the contact holes to a wet cleaning process before subjecting the bottoms of the contact holes to the dry cleaning process.

6. The method according to claim 5, wherein the first wet cleaning process for the contact holes is performed by using an oxidative acidic solution, and the second wet cleaning process for the contact holes is performed by using an oxidative alkaline solution.

7. The method according to claim 1, wherein the second wiring layer is formed by a sputtering process.

8. The method according to claim 2, wherein the conductive material comprises a metal material.

9. An apparatus for manufacturing a semiconductor device, wherein the semiconductor device comprises a base substrate, a first wiring layer provided on the base substrate, an interlayer dielectric layer provided on the first wiring layer, with contact holes being provided in the interlayer dielectric layer,
the apparatus comprising a pre-cleaning chamber, a reaction chamber, and a conveying chamber, wherein
the pre-cleaning chamber and the reaction chamber are connected to the conveying chamber respectively;
the pre-cleaning chamber is used for subjecting bottoms of the contact holes to a dry cleaning process; and
the reaction chamber is used for forming a second wiring layer on the interlayer dielectric layer, wherein the second wiring layer is electrically connected to the first wiring layer via the contact holes.

10. The apparatus according to claim 9, wherein the reaction chamber comprises a sputtering chamber or a vapor deposition chamber.

11. The apparatus according to claim 9, wherein the base substrate subjected to a dry cleaning process is moved from the pre-cleaning chamber to the reaction chamber through the conveying chamber.

12. The apparatus according to claim 9, further comprising a heating chamber connected to the conveying chamber, which is used for heating the base substrate having the contact holes formed thereon, before subjecting the bottoms of the contact holes to a dry cleaning process.

13. The apparatus according to claim 9, further comprising a loading and locking chamber connected to the conveying chamber, which is used for delivering a semiconductor device to be processed to the conveying chamber and withdrawing the semiconductor device after processing from the apparatus.

14. The method according to claim 1, wherein the second wiring layer comprises a conductive material.

15. The method according to claim 5, wherein the wet cleaning process comprises:
subjecting the contact holes to a first wet cleaning process; and
subjecting the contact holes to a second wet cleaning process.

16. The method according to claim 14, wherein the semiconductor material comprises amorphous silicon or polycrystalline silicon.

17. The method according to claim 14, wherein the conductive material comprises a metal material.
